(19) United States
(12) Patent Application Publication
(10) Pub. No.: US 2025/0324857 A1
(43) Pub. Date: Oct. 16, 2025

(54) DISPLAY DEVICE

(71) Applicant: Samsung Display Co., LTD., Yongin-si (KR)

(72) Inventors: Hyun Eok SHIN, Yongin-si (KR); Joon Yong PARK, Yongin-si (KR); Su Kyoung YANG, Yongin-si (KR); Dong Min LEE, Yongin-si (KR)

(21) Appl. No.: 19/081,673

(22) Filed: Mar. 17, 2025

(30) Foreign Application Priority Data
Apr. 16, 2024 (KR) 10-2024-0050725

(51) Int. Cl. H10K 59/122; H10K 59/80

(52) U.S. Cl. CPC H10K 59/122; H10K 59/873

(57) ABSTRACT

A display device includes a first via pattern and a second via pattern spaced apart above a substrate, a passivation layer above the first via pattern and the second via pattern, a first light-emitting element above the passivation layer, and overlapping the first via pattern, a second light-emitting element above the passivation layer, and overlapping the second via pattern, a first bank above the substrate between the first via pattern and the second via pattern, and a second bank above the first bank, and protruding beyond a side of the first bank.

### CROSS-REFERENCE TO RELATED APPLICATION

The present application claims priority to, and the benefit of, Korean Patent Application No. 10-2024-0050725 filed on Apr. 16, 2024 in the Korean Intellectual Property Office, the disclosure of which in its entirety is herein incorporated by reference.

### BACKGROUND

### 1. Field

The present disclosure relates to a display device.

### 2. Description of the Related Art

With the advancement of the information age, the demand for a display device for displaying an image has increased with various forms. For example, the display device has been applied to various electronic devices, such as a smart phone, a digital camera, a laptop computer, a navigator and a smart television. The display device may be a flat panel display device, such as a liquid crystal display device, a field emission display device and an organic light-emitting display device. Among the flat panel display devices, the light-emitting display device includes a light-emitting element in which each of pixels of a display panel may self-emit light, thereby displaying an image even without a backlight unit that provides the display panel with light.

Recently, the display device has been applied to a glasses-type device for providing virtual reality and augmented reality. To be applied to the glasses-type device, the display device is implemented at a very small size of about 2 inches or less, but it may suitably have high pixel integration so that it may be implemented at high resolution. For example, the display device may have high pixel integration of about 400 pixels per inch (PPI) or more.

### SUMMARY

The present disclosure provides a display device in which light-emitting elements or common electrodes, which are divided for each light emission area, may be formed without a mask process.

The present disclosure provides a display device in which moisture absorption or moisture permeation of a lower organic layer of a light-emitting element is reduced to enhance durability.

The aspects of the present disclosure are not limited to those mentioned above and additional aspects of the present disclosure, which are not mentioned herein, will be clearly understood by those skilled in the art from the following description of the present disclosure.

According to the display device according to one or more embodiments, an organic layer or organic pattern, which is positioned below a light-emitting element, is covered with a passivation layer, and thus may be robust against moisture absorption or moisture permeation.

According to some embodiments of the present disclosure, a display device includes a first via pattern and a second via pattern spaced apart above a substrate, a passivation layer above the first via pattern and the second via pattern, a first light-emitting element above the passivation layer, and overlapping the first via pattern, a second light-emitting element above the passivation layer, and overlapping the second via pattern, a first bank above the substrate between the first via pattern and the second via pattern, and a second bank above the first bank, and protruding beyond a side of the first bank.

The passivation layer may cover an upper surface and a side of the first via pattern and an upper surface and a side of the second via pattern.

The passivation layer may define a contact hole through which a pixel electrode of the first light-emitting element passes.

The passivation layer may include a first portion at a first height from the substrate, a second portion at a second height from the substrate, and a third portion at a third height from the substrate, the third height being greater than the first height and the second height, and the second height being greater than the first height.

The passivation layer may include one or more of silicon nitride, silicon oxynitride, or silicon oxide.

An angle between a lower surface and a side of the first via pattern may be less than about 90°.

The first via pattern and the second via pattern may include one or more of a polyimide resin, an acrylic resin, an epoxy resin, a phenolic resin, or a polyamide resin.

The display device may further include a pixel-defining layer between the passivation layer and the first bank, and including a side protruding beyond the side of the first bank.

The display device may further include a residual pattern at an edge of a first pixel electrode of the first light-emitting element below the pixel-defining layer.

The first light-emitting element may include a first pixel electrode above the passivation layer, a first light-emitting layer above the first pixel electrode, and a first common electrode above the first light-emitting layer, wherein the second light-emitting element includes a second pixel electrode above the passivation layer, a second light-emitting layer above the second pixel electrode, and a second common electrode above the second light-emitting layer and spaced from the first common electrode.

The first common electrode and the second common electrode may contact the first bank.

The display device may further include a first inorganic pattern above the first light-emitting element, and a second inorganic pattern above the second light-emitting element and spaced from the first inorganic pattern.

A portion of the first inorganic pattern may be below a lower surface of the second bank.

According to some embodiments of the present disclosure, a display device includes a first via pattern and a second via pattern spaced apart above a substrate, a first light-emitting element above the first via pattern, a second light-emitting element above the second via pattern, a first bank above the substrate, defining a first opening overlapping the first light-emitting element, and defining a second opening overlapping an area between the first light-emitting element and the second light-emitting element, and a second bank above the first bank, and protruding beyond a side of the first bank.

The second bank may define a first opening overlapping the first opening of the first bank, and a second opening overlapping the second opening of the first bank, wherein a first side of the second bank directed toward the first opening protrudes beyond a first side of the first bank directed toward the first opening, and wherein a second side of the second bank directed toward the second opening protrudes beyond a second side of the first bank directed toward the second opening.

The display device may further include a thin film transistor between the substrate and the first bank, and overlapping the second opening of the first bank.

The display device may further include a passivation layer between the first via pattern and the first light-emitting element, and between the substrate and the first bank, and a pixel-defining layer between the passivation layer and the first bank.

The second opening of the first bank may overlap the passivation layer.

At least a portion of the second opening of the first bank might not overlap the pixel-defining layer.

A thickness of the pixel-defining layer adjacent to the first bank may be greater than a thickness of the pixel-defining layer adjacent to a center of the second opening of the first bank.

The aspects according to the embodiments of the present disclosure are not limited to those mentioned above and more various aspects are included in the following description of the present disclosure.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments;

FIG. 2 is a plan view illustrating that the display device of FIG. 1 is folded and viewed from the front;

FIG. 3 is a cross-sectional view illustrating that the display device of FIG. 1 is folded and viewed from the side;

FIG. 4 is an enlarged plan view illustrating an area B of FIG. 2;

FIG. 5 is a cross-sectional view illustrating a portion of a display device according to one or more embodiments;

FIG. 6 is an enlarged cross-sectional view illustrating an area A1 of FIG. 5;

FIG. 7 is a cross-sectional view illustrating a portion of a display device according to one or more embodiments;

FIG. 8 is an enlarged cross-sectional view illustrating an area A1′ of FIG. 7;

FIGS. 9 and 10 are enlarged cross-sectional views illustrating a portion of a display device according to one or more embodiments; and

FIG. 11 is an enlarged cross-sectional view illustrating an area A2 of FIG. 10.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

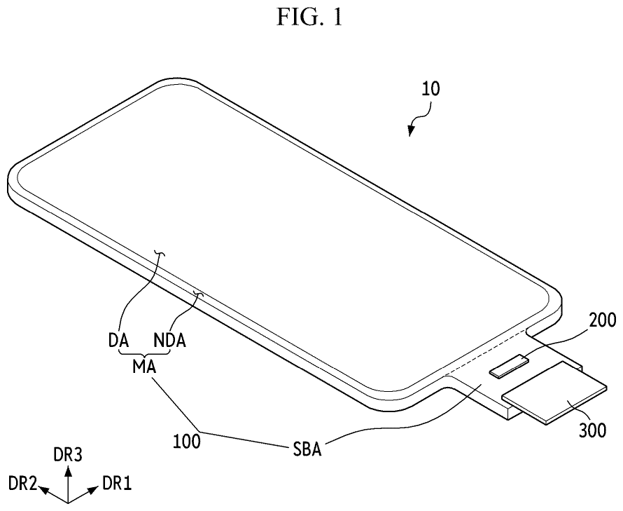

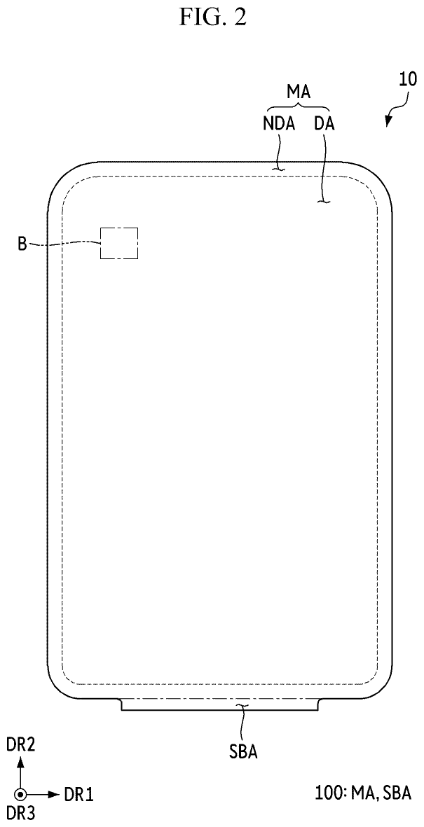

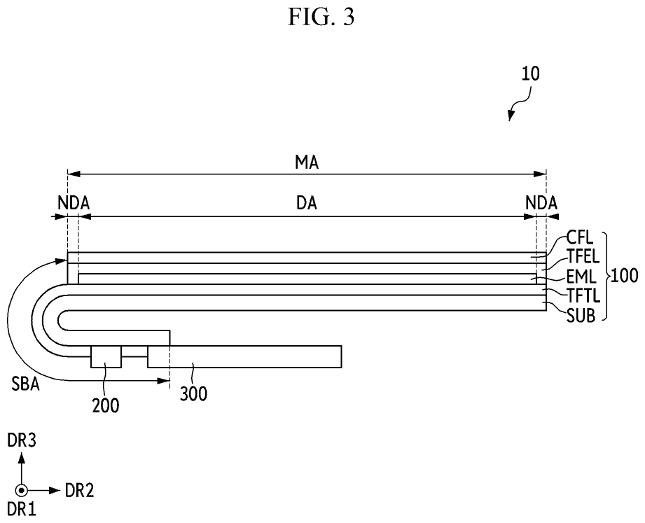

FIG. 1 is a perspective view illustrating a display device according to one or more embodiments. FIG. 2 is a plan view illustrating that the display device of FIG. 1 is folded and viewed from the front. FIG. 3 is a cross-sectional view illustrating that the display device of FIG. 1 is folded and viewed from the side.

Referring to FIG. 1, a display device 10 according to one or more embodiments is a device that displays a moving image or a still image, and may be used as a display screen of various products, such as a television, a laptop computer, a monitor, an advertising board and a device for Internet of things (IoT) as well as portable electronic devices, such as a mobile phone, a smart phone, a tablet personal computer (PC), a smart watch, a watch phone, a mobile communication terminal, an electronic diary, an electronic book, a portable multimedia player (PMP), a navigator and an ultra-mobile PC (UMPC).

The display device 10 according to one or more embodiments may be a light-emitting display device, such as an organic light-emitting display device using an organic light-emitting diode, a quantum dot light-emitting display device including a quantum dot light-emitting layer, an inorganic light-emitting display device including an inorganic semiconductor, and a micro or nano light-emitting display device including a micro or nano light-emitting diode (micro or nano LED). The following description will be based on that the display device 10 is an organic light-emitting display device, but the present disclosure is not limited thereto.

The display device 10 according to one or more embodiments may include a display panel 100, a display driver 200, and a circuit board 300.

The display panel 100 may be formed in a rectangular plane having a short side in a first direction DR1, and a long side in a second direction DR2 crossing the first direction DR1. A corner where the short side in the first direction DR1 and the long side in the second direction DR2 meet may be formed at a right angle or may be rounded to have a curvature. A planar shape of the display panel 100 is not limited to the rectangular shape, and may be formed in another polygon, circle or ellipse.

The display panel 100 may be formed to be flat, but is not limited thereto. For example, the display panel 100 may include a curved portion formed at left and right ends, having a constant curvature or a variable curvature. In addition, the display panel 100 may be flexibly formed to be curved, twisted, bent, folded or rolled.

The display panel 100 may include a main area MA and a sub area SBA.

The main area MA may include a display area DA for displaying an image and a non-display area NDA for not displaying an image.

The display area DA may occupy most of areas of the display panel 100.

The display area DA may be located at the center of the display panel 100. Pixels including a plurality of light emission areas, respectively, may be located in the display area DA to display an image. An area B of FIG. 2 may be a portion of the display area DA.

The non-display area NDA may be adjacent to the display area DA. The non-display area NDA may be an outer area of the display area DA, and may surround the display area DA (e.g., in plan view). The non-display area NDA may be an edge area of the display panel 100.

The sub-area SBA may be an area extended from one side of the main area MA. The sub-area SBA may include a flexible material capable of being subjected to bending, folding, rolling and the like. For example, when the sub-area SBA is bent, the sub-area SBA may overlap the main area MA in a thickness direction (a third direction DR3). The sub-area SBA may include a display driver 200 and a pad area connected to the circuit board 300. In one or more other embodiments, the sub-area SBA may be omitted, and the display driver 200 and the pad area may be located in the non-display area NDA.

Referring to FIG. 1, the sub-area SBA may include a display driver 200, and a circuit board 300.

The display pads PD may be located on one edge of the display panel 100. For example, the display pads PD may be located on a lower edge of the display panel 100. The display pads PD may be connected to the display driver 200 and the circuit board 300.

The display drivers 200 may generate and output signals and voltages for driving the display panel 100. In detail, the display drivers 200 may generate and output data voltages, power voltages, scan timing signals and the like. The display drivers 200 may supply a power voltage to a power line, and may supply a gate control signal to a gate driver.

The display drivers 200 may be located between the display pads PD and the display area DA in the non-display area NDA. The display drivers 200 may be attached to the non-display area NDA of the display panel 100 in a chip-on-glass (COG) method. Alternatively, the display drivers 200 may be attached to the circuit board 300 in a chip-on-plastic (COP) method.

The circuit boards 300 may be located on one edge of the display panel 100, and may be located on the display pads PD. The circuit boards 300 may be attached to the display pads PD by using a conductive adhesive member, such as an anisotropic conductive film and an anisotropic conductive adhesive. Therefore, the circuit boards 300 may be electrically connected to signal lines of the display panel 100. The circuit boards 300 may be a flexible printed circuit board or a flexible film, such as a chip-on film.

FIG. 3 is a cross-sectional view illustrating that the display device of FIG. 1 is folded and viewed from the side.

Referring to FIG. 3, the display panel 100 may include a substrate SUB, a thin film transistor layer TFTL, a light-emitting element layer EML, a thin film encapsulation layer TFEL and a color filter layer CFL.

The substrate SUB may be a base substrate or a base member. The substrate SUB may be a flexible substrate capable of being subjected to bending, folding, rolling and the like. For example, the substrate SUB may include a polymer resin, such as polyimide (PI), but is not limited thereto. In one or more other embodiments, the substrate SUB may include a glass material or a metal material.

The thin film transistor layer TFTL may be located on the substrate SUB. The thin film transistor layer TFTL may include a plurality of thin film transistors constituting a pixel circuit of pixels. The thin film transistor layer TFTL may further include scan lines, data lines, power lines, scan control lines, fan-out lines connecting the display driver 200 with the data lines, and lead lines connecting the display driver 200 with the pad area. Each of the thin film transistors may include a semiconductor area, a source electrode, a drain electrode and a gate electrode. For example, when the scan driver is formed on one side of the non-display area NDA of the display panel 100, the scan driver may include thin film transistors.

The thin film transistor layer TFTL may be located in the display area DA, the non-display area NDA, and the sub-area SBA. The thin film transistors, the scan lines, the data lines, and the power lines of the pixels of the thin film transistor layer TFTL may be located in the display area DA. The scan control lines and the fan-out lines of the thin film transistor layer TFTL may be located in the non-display area NDA. The lead lines of the thin film transistor layer TFTL may be located in the sub-area SBA.

The light-emitting element layer EML may be located on the thin film transistor layer TFTL. The light-emitting element layer EML may include a plurality of light-emitting elements, which include a first electrode, a second electrode, and a light-emitting layer to emit light, and a pixel-defining layer defining pixels. The plurality of light-emitting elements of the light-emitting element layer EML may be located in the display area DA.

In one or more embodiments, the light-emitting layer may be an organic light-emitting layer including an organic material. The light-emitting layer may include a hole-transporting layer, an organic light-emitting layer and an electron-transporting layer. When the first electrode receives a voltage through the thin film transistor of the thin film transistor layer TFTL, and when the second electrode receives a cathode voltage, holes, and electrons may be moved to the organic light-emitting layer through the hole-transporting layer and the electron-transporting layer, respectively, and may be combined with each other in the organic light-emitting layer to emit light.

In one or more other embodiments, the light-emitting element may include a quantum dot light-emitting diode including a quantum dot light-emitting layer, an inorganic light-emitting diode including an inorganic semiconductor, or a micro light-emitting diode.

The thin film encapsulation layer TFEL may cover an upper surface and sides of the light-emitting element layer EML, and may protect the light-emitting element layer EML. The thin film encapsulation layer TFEL may include at least one inorganic layer and at least one organic layer, which are intended to encapsulate the light-emitting element layer EML.

The color filter layer CFL may be located on the thin film encapsulation layer TFEL. The color filter layer CFL may include a plurality of color filters respectively corresponding to the plurality of light emission areas. Each of the color filters may selectively transmit light of a corresponding wavelength, and may block or absorb light of another wavelength. The color filter layer CFL may absorb a portion of light incident from the outside of the display device 10 to reduce reflective light due to external light. Therefore, the color filter layer CFL may reduce or prevent distortion of a color due to external light reflection from occurring.

As the color filter layer CFL is directly located on the thin film encapsulation layer TFEL, the display device 10 may not require a separate substrate for the color filter layer CFL. Therefore, a thickness of the display device 10 may be relatively small.

In some embodiments, the display device 10 may further include an optical device. The optical device may emit or receive light of an infrared, ultraviolet or visible band. For example, the optical device may be an optical sensor for sensing light incident on the display device 10, such as a proximity sensor, an illuminance sensor, a camera sensor, a fingerprint sensor, or an image sensor.

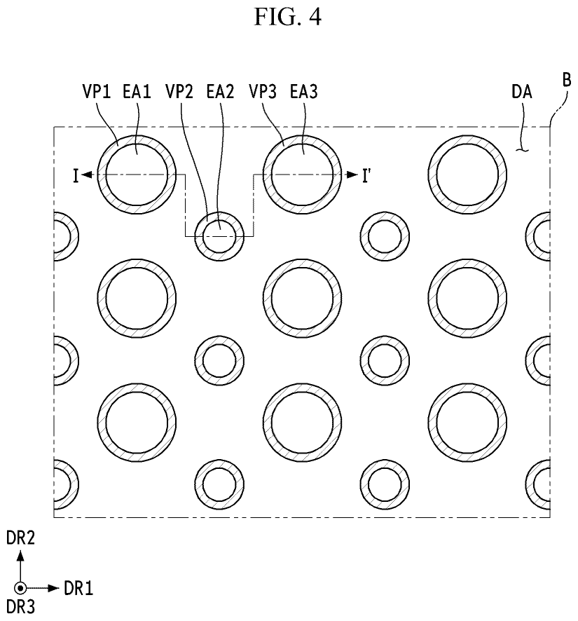

FIG. 4 is an enlarged plan view illustrating a portion of a display device according to one or more embodiments (an area B of FIG. 2). FIG. 4 may be a top view of light emission areas EA1, EA2, and EA3 and via patterns VP1, VP2, and VP3 in the display area DA as viewed from the upper side of the display device 10.

Although FIG. 4 illustrates that the light emission areas EA1, EA2, and EA3 have circular shapes, the light emission areas EA1, EA2, and EA3 may be polygons, such as triangles, squares or hexagons. The plurality of light emission areas EA1, EA2, and EA3 may be located in a PENTILE™ type, for example, a diamond PENTILE™ type (PENTILE™ being a registered trademark of Samsung Display Co., Ltd., Republic of Korea). For example, the first light emission area EA1 and the third light emission area EA3 may be spaced apart from each other in the first direction DR1, and may be alternately located in the first direction DR1 and the second direction DR2. The second light emission area EA2 may be spaced apart from another adjacent second light emission area EA2 in the first direction DR1 and the second direction DR2. The second light emission area EA2 and the first light emission area EA1, or the second light emission area EA2 and the third light emission area EA3, may be alternately located along any one direction in a plane defined by the first direction DR1 and the second direction DR2. The shape and arrangement of the plurality of light emission areas are not limited to FIG. 4.

The first to third light emission areas EA1, EA2, and EA3 may have different sizes. For example, the size of the first light emission area EA1 may be larger than that of the second light emission area EA2, and the size of the second light emission area EA2 may be smaller than that of the third light emission area EA3. The intensity of light emitted from the corresponding light emission areas EA1, EA2, and EA3 may vary depending on the sizes of the light emission areas EA1, EA2, and EA3, and a color of a screen displayed by the display device 10 may be controlled by adjusting the sizes of the light emission areas EA1, EA2, and EA3.

In the display device 10, one first light emission area EA1, one second light emission area EA2, and one third light emission area EA3, which are adjacent to one another, may form one pixel group. One pixel group may include light emission areas EA1, EA2, and EA3, which emit light of different respective colors, to represent a white gray scale, but the present disclosure is not limited thereto. Various modifications may be made in combination of the light emission areas EA1, EA2, and EA3 constituting one pixel group depending on the arrangement of the light emission areas EA1, EA2, and EA3, the color of light emitted from the light emission areas EA1, EA2, and EA3, and the like.

The plurality of via patterns VP1, VP2, and VP3 may be provided, and the via patterns VP1, VP2, and VP3 may correspond to one of the plurality of light emission areas EA1, EA2, and EA3, respectively. Central portions of the via patterns VP1, VP2, and VP3 may overlap the light emission areas EA1, EA2, and EA3, and edge portions of the via patterns VP1, VP2, and VP3 may not overlap the light emission areas EA1, EA2, and EA3. The edge portions of the via patterns VP1, VP2, and VP3 may be exposed without being covered by the light emission areas EA1, EA2, and EA3. The via patterns VP1, VP2, and VP3 may have a size larger than that of the corresponding light emission areas EA1, EA2, and EA3.

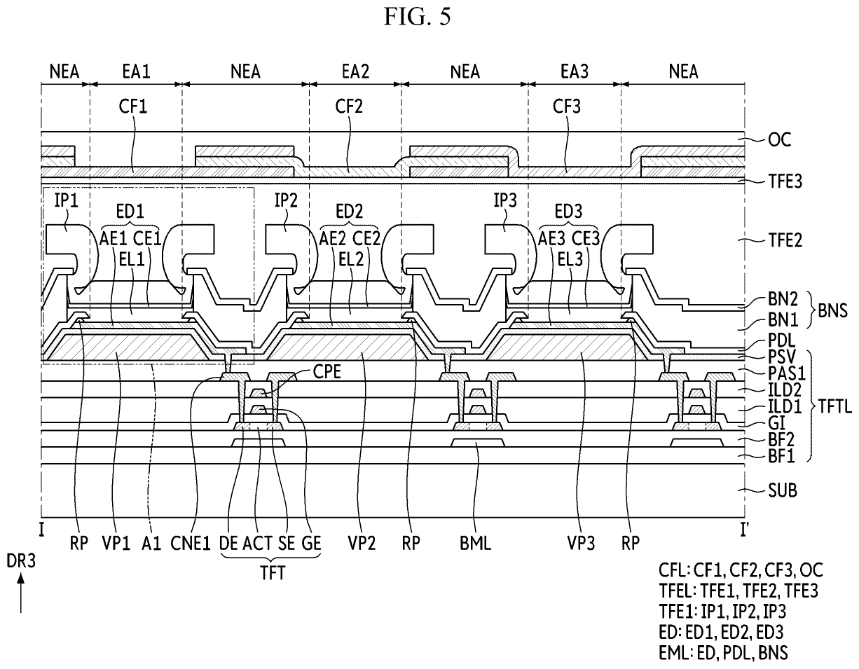

FIG. 5 is a cross-sectional view illustrating a portion of a display device according to one or more embodiments. In detail, FIG. 5 is a cross-sectional view taken along the line I-I′ of FIG. 4, illustrating a substrate SUB, a thin film transistor layer TFTL, a light-emitting element layer EML, a thin film encapsulation layer TFEL, and a color filter layer CFL.

The thin film transistor layer TFTL may include a first buffer layer BF1, a second buffer layer BF2, a thin film transistor TFT, a gate-insulating layer GI, a first interlayer insulating layer ILD1, a capacitor electrode CPE, a second interlayer insulating layer ILD2, a first connection electrode CNE1, a first passivation layer PAS1, via patterns VP1, VP2, and VP3, and a passivation layer PSV.

The first buffer layer BF1 may be located on the substrate SUB. The first buffer layer BF1 may include an inorganic layer capable of reducing or preventing permeation of the air or moisture. For example, the first buffer layer BF1 may include a plurality of inorganic layers that are alternately stacked.

The lower metal layer BML may be located on the first buffer layer BF1. For example, the lower metal layer BML may be formed of a single layer or multi-layer made of any one of molybdenum (Mo), aluminum (Al), chromium (Cr), gold (Au), titanium (Ti), nickel (Ni), neodymium (Nd), or copper (Cu), or their alloy(s).

The second buffer layer BF2 may cover the first buffer layer BF1 and the lower metal layer BML. The second buffer layer BF2 may include an inorganic layer capable of reducing or preventing permeation of the air or moisture. For example, the second buffer layer BF2 may include a plurality of inorganic layers that are alternately stacked.

The thin film transistor TFT may be located on the second buffer layer BF2, and may constitute a pixel circuit of each of a plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be located on the second buffer layer BF2. The semiconductor layer ACT may overlap the gate electrode GE in the thickness direction DR3, and may be insulated from the gate electrode GE by the gate-insulating layer GI. A portion of the semiconductor layer ACT may form the source electrode SE and the drain electrode DE by conductorizing a material of the semiconductor layer ACT.

The gate electrode GE may be located on the gate-insulating layer GI. The gate electrode GE may overlap the semiconductor layer ACT in the thickness direction DR3 with the gate-insulating layer GI interposed therebetween.

The gate-insulating layer GI may be located on the semiconductor layer ACT. For example, the gate-insulating layer GI may cover the semiconductor layer ACT and the second buffer layer BF2, and may insulate the semiconductor layer ACT from the gate electrode GE. The gate-insulating layer GI may include a contact hole through which the first connection electrode CNE1 passes.

The first interlayer insulating layer ILD1 may cover the gate electrode GE and the gate-insulating layer GI. The first interlayer insulating layer ILD1 may include a contact hole through which the first connection electrode CNE1 passes. The contact hole of the first interlayer insulating layer ILD1 may be connected to the contact hole of the gate-insulating layer GI and a contact hole of the second interlayer insulating layer ILD2.

The capacitor electrode CPE may be located on the first interlayer insulating layer ILD1. The capacitor electrode CPE may overlap the gate electrode GE in the thickness direction DR3. The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be connected to the contact hole of the first interlayer insulating layer ILD1 and the contact hole of the gate-insulating layer GI.

The first connection electrode CNE1 may be located on the second interlayer insulating layer ILD2. The first connection electrode CNE1 may electrically connect the drain electrode DE of the thin film transistor TFT with pixel electrodes AE1, AE2, and AE3. The first connection electrode CNE1 may be inserted into the contact holes formed in the second interlayer insulating layer ILD2, the first interlayer insulating layer ILD1, and the gate-insulating layer GI to contact the drain electrode DE of the thin film transistor TFT.

The first passivation layer PAS1 may cover the first connection electrode CNE1 and the second interlayer dielectric layer ILD2. The first passivation layer PAS1 may protect the thin film transistor TFT. The first passivation layer PAS1 may include a contact hole through which the pixel electrodes AE1, AE2, and AE3 pass. In one or more embodiments, the first passivation layer PAS1 may be formed of an organic layer, such as an acrylic resin, an epoxy resin, a phenolic resin, a polyamide resin, and a polyimide resin. Alternatively, the first passivation layer PAS1 may be formed of an inorganic layer, for example, a silicon nitride layer, a silicon oxynitride layer, a silicon oxide layer, a titanium oxide layer, or an aluminum oxide layer. Alternatively, the first passivation layer PAS1 may be formed of a plurality of layers of the organic or inorganic material described above.

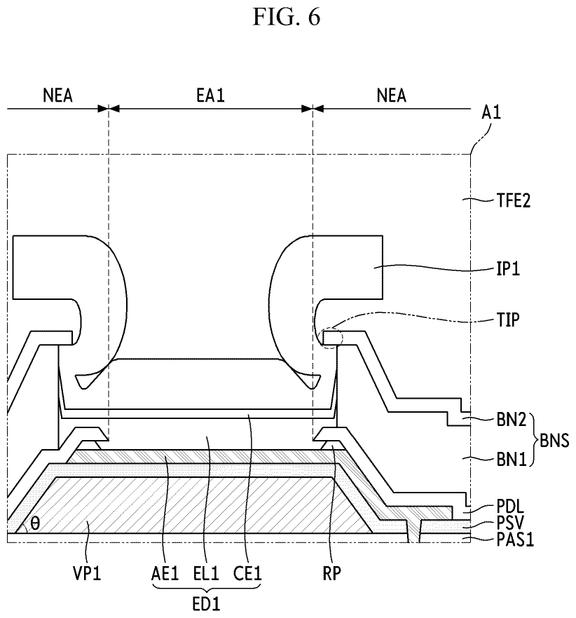

FIG. 6 is an enlarged cross-sectional view of an area A1 of FIG. 5, illustrating in detail the first via pattern VP1 and the first light emission area EA1. Hereinafter, the via patterns VP1, VP2, and VP3 will be described with respect to the first via pattern VP1 and the first light emission area EA1 by way of example.

Referring to FIGS. 5 and 6, the via patterns VP1, VP2, and VP3 may be located on the first passivation layer PAS1. The via patterns VP1, VP2, and VP3 may have a flat upper surface while filling a step difference of the thin film transistor TFT below the thin film transistor TFT. The via patterns VP1, VP2, and VP3 may include a first via pattern VP1, a second via pattern VP2, and a third via pattern VP3. The first to third via patterns VP1, VP2, and VP3 may be spaced apart from one another. Each of the via patterns VP1, VP2, and VP3 may overlap one of the plurality of light emission areas EA1, EA2, and EA3. The via patterns VP1, VP2, and VP3 may be island patterns. A cross-section of the via patterns VP1, VP2, and VP3 on a plan view may be a circle or a polygon, such as a triangle and a square.

The via patterns VP1, VP2, and VP3 may have a forward tapered shape when cut in the thickness direction DR3. The via patterns VP1, VP2, and VP3 may include sides inclined from the substrate SUB. An angle θ formed by a lower surface and sides of the via patterns VP1, VP2, and VP3 may be less than about 90°.

The via patterns VP1, VP2, and VP3 may include an organic material. In one or more embodiments, the via patterns VP1, VP2, and VP3 may include a polyimide resin, an acrylic resin, an epoxy resin, a phenolic resin, a polyamide resin, and the like. In one or more embodiments, the via patterns VP1, VP2, and VP3 may be formed by optical patterning.

Meanwhile, light-emitting layers EL1, EL2, and EL3, common electrodes CE1, CE2, and CE3 and lower inorganic encapsulation layers IP1, IP2, and IP3 of the light-emitting elements ED1, ED2, and ED3, which will be described later, may be sequentially formed for each color. After materials of the first light-emitting layer EL1, the first common electrode CE1, and the first inorganic pattern IP1 of a first color are deposited or coated on an entire surface, the first light-emitting layer EL1, the first common electrode CE1, and the first inorganic pattern IP1 remain only in the first light emission area EA1 and its peripheral area by patterning. Afterwards, the same process may be repeated for the second light-emitting layer EL2, the second common electrode CE2, and the second inorganic pattern IP2 of a second color so that the second light-emitting layer EL2, the second common electrode CE2, and the second inorganic pattern IP2 may be formed. A wet etching process or a cleaning process may be performed during the patterning process of the second color. When a via layer, on which an organic material is formed on an entire surface, or the via patterns VP1, VP2, and VP3 are exposed to a solution of the wet etching process or the cleaning process, the via layer or the via patterns VP1, VP2, and VP3 of the organic layer may absorb moisture. As the first light-emitting layer EL1 includes the organic material, it may be difficult to dry moisture of the via layer or the via patterns VP1, VP2, and VP3 through high-temperature baking during the patterning process of the second color. The remaining moisture may deteriorate reliability when the display device 10 is driven.

Referring to FIG. 6 in addition to FIG. 5, the passivation layer PSV may cover the via patterns VP1, VP2, and VP3 and the first passivation layer PAS1. The passivation layer PSV may include a contact hole through which the pixel electrodes AE1, AE2, and AE3 pass. The contact hole of the passivation layer PSV may be connected to the contact hole of the first passivation layer PAS1.

The upper surface and sides of the via patterns VP1, VP2, and VP3 are covered with a passivation layer PSV, and the lower surfaces of the via patterns VP1, VP2, and VP3 are covered with the first passivation layer PAS1, whereby permeation of moisture into the via patterns VP1, VP2, and VP3 may be reduced or prevented.

The passivation layer PSV may include a first portion located at a position of a first height from the substrate SUB, a second portion located at a position of a second height from the substrate SUB, and a third portion located at a position of a third height from the substrate SUB. The third height may be greater than the first height and the second height, and the second height may be greater than the first height. The first portion, the second portion, and the third portion of the passivation layer PSV may be sequentially located in a longitudinal direction of the substrate SUB. In other words, the second portion of the passivation layer PSV may be located between the first portion and the third portion in the longitudinal direction of the substrate SUB. The height of the passivation layer PSV refers to a vertical distance between the upper surface of the substrate SUB and a lower surface of a corresponding portion of the passivation layer PSV.

The passivation layer PSV may not be removed by the wet etching process and the cleaning process. The passivation layer PSV may include an inorganic material. In one or more embodiments, the passivation layer PSV may include silicon nitride, silicon oxynitride, silicon oxide, titanium oxide, aluminum oxide or their combination.

The light-emitting element layer EML may be located on the thin film transistor layer TFTL. The light-emitting element layer EML may include a light-emitting element ED, a pixel-defining layer PDL, and a bank structure BNS. The light-emitting element ED may include pixel electrodes AE1, AE2, and AE3, light-emitting layers EL1, EL2, and EL3 and common electrodes CE1, CE2, and CE3.

Referring to FIGS. 5 and 6, the display device 10 may include a plurality of light emission areas EA1, EA2, and EA3 located in the display area DA, and a non-light emission area NEA located between the light emission areas EA1, EA2, and EA3. The light emission areas EA1, EA2, and EA3 may be defined as areas where the pixel electrodes AE1, AE2, and AE3, the light-emitting layers EL1, EL2, and EL3 and the common electrodes CE1, CE2, and CE3 overlap one another in the thickness direction of the substrate SUB. The light emission areas EA1, EA2, and EA3 may include a first light emission area EA1, a second light emission area EA2, and a third light emission area EA3, which are spaced apart from one another, and which emit light of the same color or different colors. In one or more embodiments, the first light emission area EA1 may emit light of a first color, the second light emission area EA2 may emit light of a second color, and the third light emission area EA3 may emit light of a third color.

The display device 10 may include a plurality of light-emitting elements ED1, ED2, and ED3 located in different light emission areas EA1, EA2, and EA3. The light-emitting elements ED1, ED2, and ED3 may include a first light-emitting element ED1 located in the first light emission area EA1, a second light-emitting element ED2 located in the second light emission area EA2, and a third light-emitting element ED3 located in the third light emission area EA3.

The light-emitting elements ED1, ED2, and ED3 may include pixel electrodes AE1, AE2, and AE3, light-emitting layers EL1, EL2, and EL3 and common electrodes CE1, CE2, and CE3, respectively, and the light-emitting elements ED1, ED2, and ED3 respectively located in the different light emission areas EA1, EA2, and EA3 may emit light of different colors depending on materials of the light-emitting layers EL1, EL2, and EL3. For example, the first light-emitting element ED1 located in the first light emission area EA1 may emit first light of a red color, which has a peak wavelength in the range of about 610 nm to about 650 nm, the second light-emitting element ED2 located in the second light emission area EA2 may emit second light of a green color, which has a peak wavelength in the range of about 510 nm to about 550 nm, and the third light-emitting element ED3 located in the third light emission area EA3 may emit third light of a blue color, which has a peak wavelength in the range of about 440 nm to about 480 nm. The first to third light emission areas EA1, EA2, and EA3 constituting one pixel may include the light-emitting elements ED1, ED2, and ED3 for emitting light of different colors to represent a white gray scale. Alternatively, as the light-emitting layers EL1, EL2, and EL3 may include two or more materials for emitting light of different colors, one light-emitting layer may emit mixture light. For example, the light-emitting layers EL1, EL2, and EL3 may include a material for emitting red light and a material for emitting green light together to emit yellow light, or may include all of a material for emitting red light, a material for emitting green light, and a material for emitting blue light to emit white light.

The pixel electrodes AE1, AE2, and AE3 may be located on the passivation layer PSV. The pixel electrodes AE1, AE2, and AE3 may be located in the plurality of light emission areas EA1, EA2, and EA3, respectively, and may overlap the plurality of via patterns VP1, VP2, and VP3, respectively. The pixel electrodes AE1, AE2, and AE3 may include a first pixel electrode AE1 located in the first light emission area EA1, a second pixel electrode AE2 located in the second light emission area EA2, and a third pixel electrode AE3 located in the third light emission area EA3. The first pixel electrode AE1 may overlap the first via pattern VP1, the second pixel electrode AE2 may overlap the second via pattern VP2, and the third pixel electrode AE3 may overlap the third via pattern VP3. The first pixel electrode AE1, the second pixel electrode AE2, and the third pixel electrode AE3 may be respectively spaced apart from one another on the passivation layer PSV. A portion of the pixel electrodes AE1, AE2, and AE3 may overlap the via patterns VP1, VP2, and VP3, and another portion of the pixel electrodes AE1, AE2, and AE3 may not overlap the via patterns VP1, VP2, and VP3. The pixel electrodes AE1, AE2, and AE3 may be electrically connected to the drain electrode DE of the thin film transistor TFT through the first connection electrodes CNE1. Edges of the spaced pixel electrodes AE1, AE2, and AE3 may be covered by the pixel-defining layer PDL, so that the first to third pixel electrodes AE1, AE2, and AE3 may be insulated from one another.

The pixel electrodes AE1, AE2, and AE3 may include a transparent electrode material and/or a conductive metal material, and may have a single layered structure or a multi-layered structure. The metal material may be one or more of silver (Ag), copper (Cu), aluminum (Al), nickel (Ni), lanthanum (La), titanium (Ti), or titanium nitride (TiN). The transparent electrode material may be one or more of Indium Tin Oxide (ITO), Indium Zinc Oxide (IZO), or Indium Tin Zinc Oxide (ITZO). In one or more embodiments, the pixel electrodes AE1, AE2, and AE3 may have a multi-layered structure that includes a metal material layer and a transparent electrode material layer.

The light-emitting layers EL1, EL2, and EL3 may be located on the pixel electrodes AE1, AE2, and AE3. The light-emitting layers EL1, EL2, and EL3 may be organic light-emitting layers made of an organic material, and may be formed on the pixel electrodes AE1, AE2, and AE3 through a deposition process. The light-emitting layers EL1, EL2, and EL3 may have a multi-layered structure, and each of a hole injection material, a hole-transporting material, a light-emitting material, an electron-transporting material, and/or an electron injection material may constitute a layer. When the thin film transistor TFT applies a voltage (e.g., predetermined voltage) to the pixel electrodes AE1, AE2, and AE3 of the light-emitting elements ED1, ED2, and ED3 and the common electrodes CE1, CE2, and CE3 of the light-emitting elements ED1, ED2, and ED3 receive a common voltage or a cathode voltage, holes and electrons may be injected and transported, and may be combined with each other in the light-emitting layers EL1, EL2, and EL3 to emit light.

The light-emitting layers EL1, EL2, and EL3 may include a first light-emitting layer EL1, a second light-emitting layer EL2, and a third light-emitting layer EL3, which are located in the different light emission areas EA1, EA2, and EA3, respectively. The first light-emitting layer EL1 may be located on the first pixel electrode AE1 in the first light emission area EA1, the second light-emitting layer EL2 may be located on the second pixel electrode AE2 in the second light emission area EA2, and the third light-emitting layer EL3 may be located on the third pixel electrode AE3 in the third light emission area EA3. The first light-emitting layer EL1 may overlap the first via pattern VP1, the second light-emitting layer EL2 may overlap the second via pattern VP2, and the third light-emitting layer EL3 may overlap the third via pattern VP3. The plurality of light-emitting layers EL1, EL2, and EL3 may emit light of different colors, respectively, or one of the light-emitting layers EL1, EL2, and EL3 may emit mixture light. In one or more embodiments, the first light-emitting layer EL1 may emit red light, the second light-emitting layer EL2 may emit green light, and the third light-emitting layer EL3 may emit blue light.

The light-emitting layers EL1, EL2, and EL3 may be located on an upper surface of the pixel-defining layer PDL. In one or more embodiments, a side of a residual pattern RP may be more recessed than that of the pixel-defining layer PDL, and a portion of the light-emitting layers EL1, EL2, and EL3 may be located in spaces between the pixel electrodes AE1, AE2, and AE3 and the pixel-defining layer PDL. In one or more embodiments, the light-emitting layers EL1, EL2, and EL3 may contact the pixel-defining layer PDL, the residual pattern RP, and the pixel electrodes AE1, AE2, and AE3.

The common electrodes CE1, CE2, and CE3 may be located on the light-emitting layers EL1, EL2, and EL3. The common electrodes CE1, CE2, and CE3 may include a transparent conductive material so that light generated from the light-emitting layers EL1, EL2, and EL3 may be emitted. The common electrodes CE1, CE2, and CE3 may receive a common voltage or a low potential voltage. When the pixel electrodes AE1, AE2, and AE3 receive a voltage corresponding to the data voltage while the common electrodes CE1, CE2, and CE3 receives a low potential voltage, a potential difference may be formed between the pixel electrodes AE1, AE2, and AE3 and the common electrodes CE1, CE2, and CE3, whereby the light-emitting layers EL1, EL2, and EL3 may emit light.

The common electrodes CE1, CE2, and CE3 may include a first common electrode CE1, a second common electrode CE2, and a third common electrode CE3, which are located in the different light emission areas EA1, EA2, and EA3, respectively. The first common electrode CE1 may be located on the first light-emitting layer EL1 in the first light emission area EA1, the second common electrode CE2 may be located on the second light-emitting layer EL2 in the second light emission area EA2, and the third common electrode CE3 may be located on the third light-emitting layer EL3 in the third light emission area EA3. The first common electrode CE1 may overlap the first via pattern VP1, the second common electrode CE2 may overlap the second via pattern VP2, and the third common electrode CE3 may overlap the third via pattern VP3. The first to third common electrodes CE1, CE2, and CE3 may be spaced apart from one another.

In one or more embodiments, a capping layer may be selectively located on the common electrodes CE1, CE2, and CE3. The capping layer may include an organic material or an inorganic insulating material to cover patterns located on the light-emitting elements ED1, ED2, and ED3. The capping layer may reduce or prevent damage to the light-emitting elements ED1, ED2, and ED3 due to the external air. In one or more embodiments, the capping layer may include an organic material, such as a-NPD, NPB, TPD, m-MTDATA, Alq₃, LiF, and/or CuPc or an inorganic material, such as aluminum oxide, titanium oxide, tantalum oxide, hafnium oxide, zinc oxide, silicon oxide, silicon nitride, and/or silicon oxynitride.

The capping layer may include a first capping layer, a second capping layer, and a third capping layer, which are located in the different light emission areas EA1, EA2, and EA3, respectively. The first to third capping layers may be spaced apart from one another.

The pixel-defining layer PDL may be located on the passivation layer PSV to expose the upper surfaces of the pixel electrodes AE1, AE2, and AE3. The pixel-defining layer PDL may have a side for defining the light emission areas EA1, EA2, and EA3.

The pixel-defining layer PDL may include an inorganic insulating material. The pixel-defining layer PDL may include at least one of a silicon nitride layer, a silicon oxynitride layer, a silicon oxide layer, a titanium oxide layer, an aluminum oxide layer, a tantalum oxide layer, a hafnium oxide layer, a zinc oxide layer, or an amorphous silicon layer, but is not limited thereto.

According to one or more embodiments, the pixel-defining layer PDL is located on the edges of the pixel electrodes AE1, AE2, and AE3, and may be spaced apart from the upper surfaces of the pixel electrodes AE1, AE2, and AE3. The pixel-defining layer PDL may not directly contact the upper surfaces of the pixel electrodes AE1, AE2, and AE3 while partially overlapping the upper surfaces of the pixel electrodes AE1, AE2, and AE3 in the thickness direction DR3 of the substrate SUB, and the residual pattern RP may be located between the pixel-defining layer PDL and the pixel electrodes AE1, AE2, and AE3. However, the pixel-defining layer PDL may direly contact the sides of the pixel electrode AE1, AE2, and AE3. The side of the pixel-defining layer PDL may protrude toward the light emission areas EA1, EA2, and EA3 (e.g., in plan view) to a greater degree than a side of a second bank BN2.

The residual pattern RP may be located on the edge of each of the pixel electrodes AE1, AE2, and AE3. The pixel-defining layer PDL may not directly contact the upper surfaces of the pixel electrodes AE1, AE2, and AE3 due to the residual pattern RP. In a manufacturing process of the display device 10, a portion of a sacrificial layer located on the pixel electrodes AE1, AE2, and AE3 may be removed so that the residual pattern RP may be formed. The residual pattern RP may include a metal or an oxide semiconductor material. In the drawing, the side of the residual pattern RP, which is directed toward the light emission areas EA1, EA2, and EA3, is only illustrated as being more recessed than the side of the pixel-defining layer PDL, but the present disclosure is not limited thereto. The side of the residual pattern RP may protrude to a greater degree toward the light emission areas EA1, EA2, and EA3 than the side of the pixel-defining layer PDL, or may be aligned with the side of the pixel-defining layer PDL.

The display device 10 may include a bank structure BNS located on the pixel-defining layer PDL. The bank structure BNS may have a structure in which banks BN1 and BN2 including their respective materials different from each other are sequentially stacked, and may include, or define, a plurality of openings that overlap the light emission areas EA1, EA2, and EA3. The bank structure BNS may overlap the non-light emission area NEA located among the light emission areas EA1, EA2, and EA3, and may overlap a light-blocking area of the color filters CF1, CF2, and CF3, which will be described later. The bank structure BNS may be located among the via patterns VP1, VP2, and VP3, and may overlap a gap among the via patterns VP1, VP2, and VP3.

The first bank BN1 may be located on the pixel-defining layer PDL. A side of the first bank BN1 may be more recessed than that of the pixel-defining layer PDL in an opposite direction of a direction directed toward the light emission areas EA1, EA2, and EA3. The side of the first bank BN1 may be more recessed than that of the second bank BN2, which will be described later, in the opposite direction of the direction directed toward the light emission areas EA1, EA2, and EA3.

According to one or more embodiments, the first bank BN1 may include a metal material. In one or more embodiments, the first bank BN1 may include aluminum (Al), an oxide of aluminum (Al), or an alloy of aluminum (Al).

The common electrode CE1, CE2, and CE3 may directly contact the side of the first bank BN1. The ends of the common electrodes CE1, CE2, and CE3 may contact the side of the first bank BN1. The common electrodes CE1, CE2, and CE3 of the spaced light-emitting elements ED1, ED2, and ED3 may directly contact the first bank BN1, and the first bank BN1 may include a conductive material so that the common electrodes CE1, CE2, and CE3 may be electrically connected to one another through the first bank BN1.

According to one or more embodiments, the light-emitting layers EL1, EL2, and EL3 may directly contact the side of the first bank BN1. An area in which the common electrodes CE1, CE2, and CE3 contact the side of the first bank BN1 may be greater than an area in which the light-emitting layers EL1, EL2, and EL3 contact the side of the first bank BN1. The common electrodes CE1, CE2, and CE3 may be located on the side of the first bank BN1 to reach a larger area than the light-emitting layers EL1, EL2, and EL3, or to reach a higher position of the side of the first bank BN1. Because the common electrodes CE1, CE2, and CE3 of the different light-emitting elements ED1, ED2, and ED3 are electrically connected to one another through the first bank BN1, it may be suitable that the common electrodes CE1, CE2, and CE3 contact the first bank BN1 in more areas.

The first bank BN1 may have an upper surface at a higher position than the common electrodes CE1, CE2, and CE3. A height from the substrate SUB to the upper surface of the first bank BN1 may be greater than a height from the substrate SUB to the common electrodes CE1, CE2, and CE3.

The second bank BN2 may be located on the first bank BN1. The second bank BN2 may include/define openings that respectively overlap the light emission areas EA1, EA2, and EA3, and each of the openings may include a side. The second bank BN2 may include a tip TIP or eave that protrudes to an area extending past the first bank BN1 (e.g., in plan view). The side of the second bank BN2 may protrude toward the light emission areas EA1, EA2, and EA3 to a greater degree than the side of the first bank BN1.

As the side of the second bank BN2 has a shape that protrudes further toward the light emission areas EA1, EA2, and EA3 than the side of the first bank BN1 (e.g., in plan view), an undercut structure of the first bank BN1 may be formed below the tip TIP of the second bank BN2.

In the display device 10 according to one or more embodiments, the bank structure BNS may include a tip TIP protruding toward the light emission areas EA1, EA2, and EA3 (e.g., in plan view) so that the light-emitting layers EL1, EL2, and EL3 and the common electrodes CE1, CE2, and CE3, which are spaced apart from each other, may be formed by deposition and etching processes, as opposed to a mask process. Also, different layers may be individually formed in the different light emission areas EA1, EA2, and EA3 even through a deposition process. For example, although the light-emitting layers EL1, EL2, and EL3 of the light-emitting elements ED1, ED2, and ED3 and the common electrodes CE1, CE2, and CE3 are formed by the deposition process without using a mask, the deposited materials may be disconnected with the bank structure BNS interposed therebetween by the tip TIP of the second bank BN2 without being connected among the light emission areas EA1, EA2, and EA3. After a material for forming a corresponding layer is formed on an entire surface of the display device 10, different layers may be individually formed in the different light emission areas EA1, EA2, and EA3 through a process of removing a layer formed in an undesired area through etching. In the display device 10, the different light-emitting elements ED1, ED2, and ED3 may be respectively formed for the light emission areas EA1, EA2, and EA3 through deposition and etching processes without using a mask process, unnecessary elements in the display device 10 may be omitted, and a size of the non-display area NDA may be reduced or minimized.

The second bank BN2 may include a metal material that is different from the metal material of the first bank BN1. The metal material of the second bank BN2 is removed by dry etching together with the metal material of the first bank BN1, but with respect to wet etching, may be any material that has an etching rate that is slower than (e.g., significantly slower than) that of the first bank BN1 or that is not to be etched. In one or more embodiments, the first bank BN1 may include aluminum (Al), an oxide of aluminum (Al) or an alloy of aluminum (Al), and the second bank BN2 may include titanium (Ti), an oxide of titanium (Ti), or an alloy of titanium (Ti).

The tip TIP of the second bank BN2 may overlap the common electrodes CE1, CE2, and CE3, the light-emitting layers EL1, EL2, and EL3 and the pixel-defining layer PDL in the direction DR3 perpendicular to the substrate SUB. The common electrodes CE1, CE2, and CE3 may be formed below a lower surface of the tip TIP of the second bank BN2. One end and the other end of each of the common electrodes CE1, CE2, and CE3 may overlap the second bank BN2 in the thickness direction DR3 of the substrate.

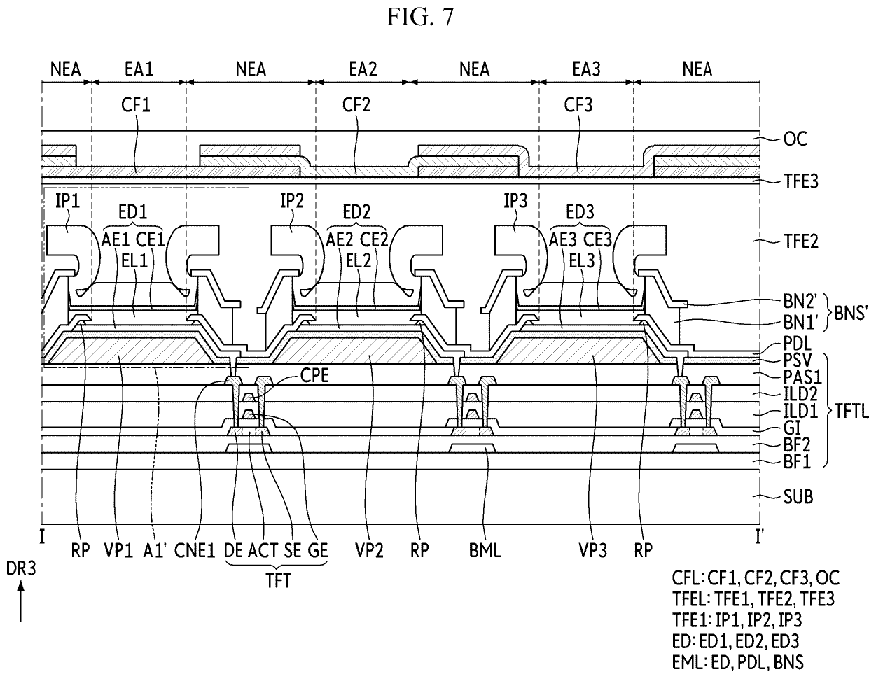

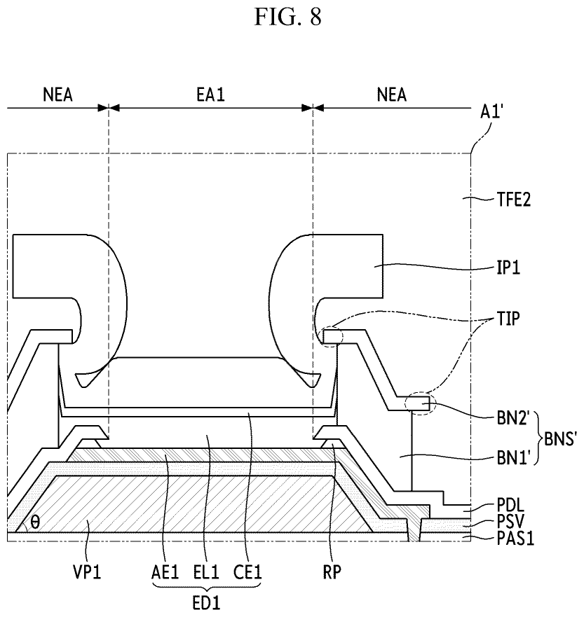

FIG. 7 is a cross-sectional view illustrating a portion of a display device according to one or more embodiments, and FIG. 8 is an enlarged cross-sectional view illustrating an area A1′ of FIG. 7.

Referring to FIG. 7, the thin film encapsulation layer TFEL may be located on the light-emitting elements ED1, ED2, and ED3 and the bank structure BNS, and may cover the plurality of light-emitting elements ED1, ED2, and ED3 and the bank structure BNS. The thin film encapsulation layer TFEL may include at least one inorganic layer to reduce or prevent permeation of oxygen or moisture into the light-emitting element layer EML. The thin film encapsulation layer TFEL may include at least one organic layer to protect the light-emitting element layer EML from particles, such as dust.

In one or more embodiments, the thin film encapsulation layer TFEL may include a lower inorganic encapsulation layer TFE1, an organic encapsulation layer TFE2, and an upper inorganic encapsulation layer TFE3, which are sequentially stacked.

Each of the lower inorganic encapsulation layer TFE1 and the upper inorganic encapsulation layer TFE3 may include one or more inorganic insulating materials. The inorganic insulating material may be any one of silicon oxide, silicon nitride and silicon oxynitride, and may be, for example, aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. The polymer-based material may include an acrylic resin, an epoxy-based resin, polyimide, and polyethylene. For example, the organic encapsulation layer TFE2 may include an acrylic resin, for example, polymethyl methacrylate, polyacrylic acid, etc. The organic encapsulation layer TFE2 may be formed by hardening a monomer or coating a polymer.

The lower inorganic encapsulation layer TFE1 may be located on the light-emitting elements ED1, ED2, and ED3 and the bank structure BNS. The lower inorganic encapsulation layer TFE1 may include a first inorganic pattern IP1, a second inorganic pattern IP2, and a third inorganic pattern IP3, which respectively correspond to the different light emission areas EA1, EA2, and EA3. Each of the first inorganic pattern IP1, the second inorganic pattern IP2, and the third inorganic pattern IP3 may include an inorganic insulating material to cover the light-emitting elements ED1, ED2, and ED3. The first inorganic pattern IP1, the second inorganic pattern IP2, and the third inorganic pattern IP3 may reduce or prevent damage to the light-emitting elements ED1, ED2, and ED3 due to the external air.

The lower inorganic encapsulation layers TFE1: IP1, IP2, and IP3 may be formed through a chemical vapor deposition (CVD) method, and thus may be formed along a step difference of the deposited layers. For example, the first inorganic pattern IP1, the second inorganic pattern IP2, and the third inorganic pattern IP3 may form a thin film even below an undercut due to the tip of the bank structure BNS. The lower inorganic encapsulation layers IP1, IP2, and IP3 may be located along (e.g., next to) the upper surface, the side, and the lower surface of the second bank BN2, the side of the first bank BN1, and the upper surfaces of the common electrodes CE1, CE2, and CE3, respectively. For example, the lower inorganic encapsulation layers IP1, IP2, and IP3 may contact the lower surface of the second bank BN2 to reduce or prevent moisture permeation from the external air from occurring.

The first inorganic pattern IP1 does not overlap the second light-emitting element ED2 and the third light-emitting element ED3, and may be located only on the first light-emitting element ED1 and on the bank structure BNS near the first light-emitting element ED1. The second inorganic pattern IP2 does not overlap the first light-emitting element ED1 and the third light-emitting element ED3, and may be located only on the second light-emitting element ED2 and on the bank structure BNS near the second light-emitting element ED2. The third inorganic pattern IP3 does not overlap the first light-emitting element ED1 and the second light-emitting element ED2, and may be located only on the third light-emitting element ED3 and on the bank structure BNS near the third light-emitting element ED3.

The first inorganic pattern IP1 may be formed after the first common electrode CE1 is formed, the second inorganic pattern IP2 may be formed after the second common electrode CE2 is formed, and the third inorganic pattern IP3 may be formed after the third common electrode CE3 is formed. The first inorganic pattern IP1, the second inorganic pattern IP2, and the third inorganic pattern IP3 may be spaced apart from one another on the bank structure BNS.

The lower inorganic encapsulation layers IP1, IP2, and IP3 are respectively located on the upper surfaces of the light-emitting elements ED1, ED2, and ED3 and the lower surfaces of the second bank BN2 near the light-emitting elements ED1, ED2, and ED3, and may be spaced apart from the upper surface of the second bank BN2. That is, the lower inorganic encapsulation layers IP1, IP2, and IP3 may have an undercut structure on the second bank BN2. The space between the lower inorganic encapsulation layers IP1, IP2, and IP3 and the upper surface of the second bank BN2 may be a space from which materials of the light-emitting layers EL1, EL2, and EL3 and the common electrodes CE1, CE2, and CE3, which are deposited on the entire surface, are removed.

The organic encapsulation layer TFE2 is located on the bank structure BNS and the lower inorganic encapsulation layers IP1, IP2, and IP3. A portion of the organic encapsulation layer TFE2 may be located in the space between the lower inorganic encapsulation layers IP1, IP2, and IP3 and the upper surface of the second bank BN2. In the area where the second bank BN2 overlaps the lower inorganic encapsulation layers IP1, IP2, and IP3, the second bank BN2, the organic encapsulation layer TFE2, and the lower inorganic encapsulation layers IP1, IP2, and IP3 may be sequentially located. In the tip TIP area, the organic encapsulation layer TFE2 and the lower inorganic encapsulation layers IP1, IP2, and IP3 may be sequentially located on the second bank BN2, and the organic encapsulation layer TFE2 may be located again on the lower inorganic encapsulation layers IP1, IP2, and IP3. In other words, a portion of the organic encapsulation layer TFE2 may be located between the upper surface of the second bank BN2 and the lower inorganic encapsulation layers IP1, IP2, and IP3 on the tip TIP of the second bank BN2, and another portion thereof may be located on the lower inorganic encapsulation layers IP1, IP2, and IP3.

In one or more embodiments, the entire upper surface of the second bank BN2 may contact the organic encapsulation layer TFE2. A first lower surface of the lower inorganic encapsulation layers IP1, IP2, and IP3 may be a surface facing the upper surface of the second bank BN2, and the first lower surface of the lower inorganic encapsulation layers IP1, IP2, and IP3 may contact the organic encapsulation layer TFE2. The organic encapsulation layer TFE2 may contact the side of the second bank BN2.

The upper inorganic encapsulation layer TFE3 may be located on the organic encapsulation layer TFE2. The upper inorganic encapsulation layer TFE3 may include aluminum oxide, titanium oxide, tantalum oxide, hafnium oxide, zinc oxide, silicon oxide, silicon nitride, and/or silicon oxynitride.

The display device 10 may include a plurality of color filters CF1, CF2, and CF3 located on the light emission areas EA1, EA2, and EA3. Each of the plurality of color filters CF1, CF2, and CF3 may include a filtering pattern area and a light-blocking area. The filtering pattern area may be formed to overlap the light emission areas EA1, EA2, and EA3 or the openings of the bank structures BNS, and may form an emission area through which light emitted from the light emission areas EA1, EA2, and EA3 is emitted. The light-blocking area is an area in which a plurality of color filters CF1, CF2, and CF3 are stacked so that light cannot be transmitted, and may overlap the non-light emission area NEA.

The color filters CF1, CF2, and CF3 may include a first color filter CF1, a second color filter CF2, and a third color filter CF3, which correspond to the different light emission areas EA1, EA2, and EA3, respectively. The color filters CF1, CF2, and CF3 may include a colorant, such as a dye or pigment for absorbing light of another wavelength band other than light of a corresponding wavelength band, and may correspond to colors of the light emitted from the light emission areas EA1, EA2, and EA3. For example, the first color filter CF1 may be a red color filter overlapping the first light emission area EA1, for transmitting only first light of a red color. The second color filter CF2 may be a green color filter overlapping the second light emission area EA2, for transmitting only second light of a green color. The third color filter CF3 may be a blue color filter overlapping the third light emission area EA3, for transmitting only third light of a blue color.

As the color filters CF1, CF2, and CF3 overlap one another, the display device 10 may reduce the intensity of reflective light due to the external light. Furthermore, the display device 10 may control a color sense of the reflective light due to external light by adjusting a layout, a shape, an area, and the like of the color filters CF1, CF2, and CF3 on the plan view.

An overcoat layer OC may be located on the color filters CF1, CF2, and CF3 to planarize upper ends of the color filters CF1, CF2, and CF3. The overcoat layer OC may be a colorless light-transmissive layer having no color of a visible light band. For example, the overcoat layer OC may include a colorless light-transmissive organic material, such as an acrylic resin.

A bank structure BNS' of FIGS. 7 and 8 may have a narrower width than the bank structure BNS of FIGS. 5 and 6. As the via patterns VP1, VP2, and VP3 are removed from a portion of the non-light emission area NEA, the bank structure BNS including a metal may become close to the thin film transistor TFT of the thin film transistor layer TFTL or a metal line, and capacitance of the capacitor may be changed. To reduce or prevent the likelihood of this, a width of the bank structure may be narrowed.

The bank structure BNS' may include/define an opening in the non-light emission area NEA. The opening of the bank structure BNS' may overlap the thin film transistor TFT. The second bank BN2′ may include not only a tip TIP in an area directed toward the light emission areas EA1, EA2, and EA3, but also may include a tip TIP in an area directed toward the center of the non-light emission area NEA. The second bank BN2′ may include a side protruding more toward the center of the non-light emission area NEA than the first bank BN1′ (e.g., in plan view).

The pixel-defining layer PDL may be exposed in the opening of the bank structure BNS′. In one or more embodiments, the pixel-defining layer PDL exposed in the opening may be covered with the organic encapsulation layer TFE2. In one or more embodiments, the pixel-defining layer PDL exposed in the opening may be covered with the same material as that of any one of the first to third inorganic patterns IP1, IP2, and IP3 of the lower inorganic encapsulation layer TFE1.

The elements of FIGS. 7 and 8 are the same as those of FIGS. 5 and 6 except the bank structure BNS′, and thus their repeated description will be omitted.

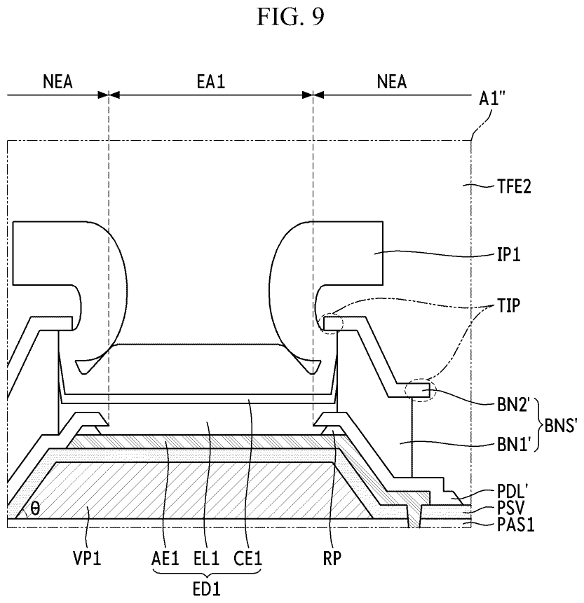

FIG. 9 is an enlarged cross-sectional view illustrating a portion of a display device according to one or more embodiments.

The pixel-defining layer PDL′ of FIG. 9 is different from the pixel-defining layer PDL of FIG. 8 in that the pixel-defining layer PDL′ is removed from a partial area of the non-light emission area NEA. The pixel-defining layer PDL′ exposed by an etchant during patterning for each color of the light-emitting elements ED1, ED2, and ED3 and the lower inorganic encapsulation layers IP1, IP2, and IP3 may be removed, and the passivation layer PSV may be exposed. The pixel-defining layer PDL′ may overlap the second bank BN2′, and an opening may be formed in the non-light emission area NEA.

At least a portion of the opening of the bank structure BNS' may not overlap the pixel-defining layer PDL′, and the passivation layer PSV may be exposed. In one or more embodiments, the passivation layer PSV exposed in the opening may be covered with the organic encapsulation layer TFE2. In one or more embodiments, the passivation layer PSV exposed in the opening may be covered with the same material as that of any one of the first to third inorganic patterns IP1, IP2, and IP3 of the lower inorganic encapsulation layer TFE1.

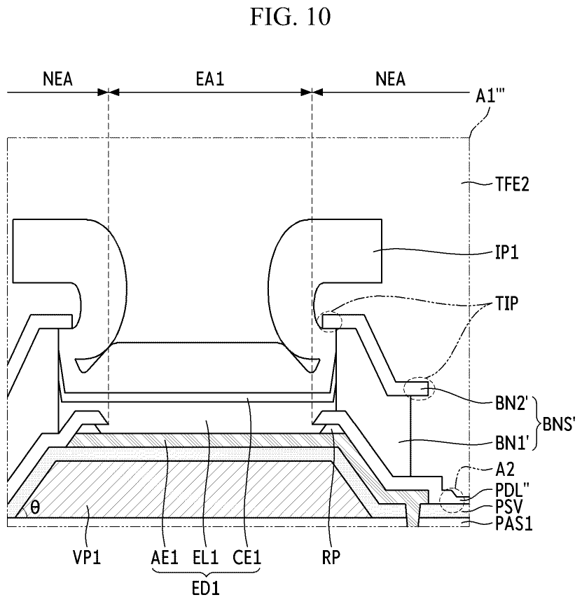

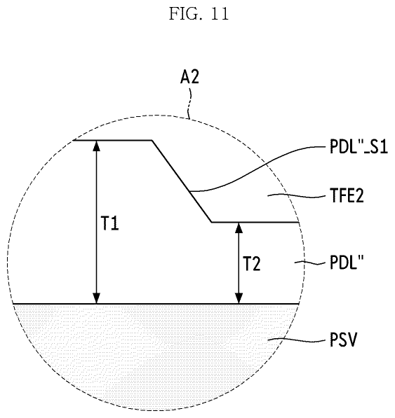

FIG. 10 is an enlarged cross-sectional view illustrating a portion of a display device according to one or more embodiments, and FIG. 11 is an enlarged cross-sectional view illustrating an area A2 of FIG. 10.

A pixel-defining layer PDL″ of FIGS. 10 and 11 is different from the pixel-defining layer PDL of FIG. 8 in that a partial thickness is removed from the non-light emission area NEA. The pixel-defining layer PDL″ is the same as the pixel-defining layer PDL′ of FIG. 9 in that the pixel-defining layer PDL″ exposed by an etchant during patterning for each color of the light-emitting elements ED1, ED2, and ED3 and the lower inorganic encapsulation layers IP1, IP2, and IP3 is removed, but only a partial thickness of the pixel-defining layer PDL″ in the area exposed by the etchant is not removed, as opposed to a total thickness.

Referring to FIG. 11, a thickness of the pixel-defining layer PDL″ may vary based on a middle side PDL″_S1. A thickness T1 of the pixel-defining layer PDL adjacent to the bank structure BNS' may be greater than a thickness T2 of the pixel-defining layer PDL adjacent to the center of the non-light emission area NEA or the center of the opening of the bank structure.

Although the embodiments of the present disclosure have been described with reference to the accompanying drawings, it will be apparent to those skilled in the art that the present disclosure can be embodied in other specific forms without departing from the technical spirits and essential characteristics. Thus, the above embodiments are to be considered in all respects as illustrative and not restrictive.

It should be understood that embodiments described herein should be considered in a descriptive sense and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a first via pattern and a second via pattern spaced apart above a substrate;
a passivation layer above the first via pattern and the second via pattern;
a first light-emitting element above the passivation layer, and overlapping the first via pattern;
a second light-emitting element above the passivation layer, and overlapping the second via pattern;
a first bank above the substrate between the first via pattern and the second via pattern; and
a second bank above the first bank, and protruding beyond a side of the first bank.

2. The display device of claim 1, wherein the passivation layer covers an upper surface and a side of the first via pattern and an upper surface and a side of the second via pattern.

3. The display device of claim 1, wherein the passivation layer defines a contact hole through which a pixel electrode of the first light-emitting element passes.

4. The display device of claim 1, wherein the passivation layer comprises a first portion at a first height from the substrate, a second portion at a second height from the substrate, and a third portion at a third height from the substrate, the third height being greater than the first height and the second height, and the second height being greater than the first height.

5. The display device of claim 1, wherein the passivation layer comprises one or more of silicon nitride, silicon oxynitride, or silicon oxide.

6. The display device of claim 1, wherein an angle between a lower surface and a side of the first via pattern is less than about 90°.

7. The display device of claim 1, wherein the first via pattern and the second via pattern comprises one or more of a polyimide resin, an acrylic resin, an epoxy resin, a phenolic resin, or a polyamide resin.

8. The display device of claim 1, further comprising a pixel-defining layer between the passivation layer and the first bank, and comprising a side protruding beyond the side of the first bank.

9. The display device of claim 8, further comprising a residual pattern at an edge of a first pixel electrode of the first light-emitting element below the pixel-defining layer.

10. The display device of claim 1, wherein the first light-emitting element comprises a first pixel electrode above the passivation layer, a first light-emitting layer above the first pixel electrode, and a first common electrode above the first light-emitting layer, and
wherein the second light-emitting element comprises a second pixel electrode above the passivation layer, a second light-emitting layer above the second pixel electrode, and a second common electrode above the second light-emitting layer and spaced from the first common electrode.

11. The display device of claim 10, wherein the first common electrode and the second common electrode contact the first bank.

12. The display device of claim 1, further comprising:
a first inorganic pattern above the first light-emitting element; and
a second inorganic pattern above the second light-emitting element and spaced from the first inorganic pattern.

13. The display device of claim 12, wherein a portion of the first inorganic pattern is below a lower surface of the second bank.

14. A display device comprising:
a first via pattern and a second via pattern spaced apart above a substrate;
a first light-emitting element above the first via pattern;
a second light-emitting element above the second via pattern;
a first bank above the substrate, defining a first opening overlapping the first light-emitting element, and defining a second opening overlapping an area between the first light-emitting element and the second light-emitting element; and
a second bank above the first bank, and protruding beyond a side of the first bank.

15. The display device of claim 14, wherein the second bank defines a first opening overlapping the first opening of the first bank, and a second opening overlapping the second opening of the first bank,
wherein a first side of the second bank directed toward the first opening protrudes beyond a first side of the first bank directed toward the first opening, and
wherein a second side of the second bank directed toward the second opening protrudes beyond a second side of the first bank directed toward the second opening.

16. The display device of claim 14, further comprising a thin film transistor between the substrate and the first bank, and overlapping the second opening of the first bank.

17. The display device of claim 14, further comprising:
a passivation layer between the first via pattern and the first light-emitting element, and between the substrate and the first bank; and
a pixel-defining layer between the passivation layer and the first bank.

18. The display device of claim 17, wherein the second opening of the first bank overlaps the passivation layer.

19. The display device of claim 17, wherein at least a portion of the second opening of the first bank does not overlap the pixel-defining layer.

20. The display device of claim 17, wherein a thickness of the pixel-defining layer adjacent to the first bank is greater than a thickness of the pixel-defining layer adjacent to a center of the second opening of the first bank.
